(19) United States
(12) Patent Application Publication
(10) Pub. No.: US 2007/0087115 A1
(43) Pub. Date: Apr. 19, 2007

(54) Method for applying a paste-like mass

(75) Inventor: Josef Schucker, Karlsruhe (DE)

Correspondence Address: WILLIAM COLLARD;COLLARD & ROE, P.C., 1077 NORTHERN BOULEVARD, ROSLYN, NY, 11576, US

(73) Assignee: SCA Schucker GmbH & Co. KG

(21) Appl. No.: 11/581,131

(22) Filed: Oct. 13, 2006

(30) Foreign Application Priority Data
Oct. 14, 2005 (DE) 10 2005 049 695.4

(51) Int. Cl. C23C 16/52; B05D 5/10

(52) U.S. Cl. 427/8; 427/207.1

(57) ABSTRACT

A method and device for applying a paste-like mass having an adhesive or sealant that can cure and consists of at least two components, onto a work piece. The mass is formed in a mixing chamber of an application head by mixing at least one first and one second adhesive or sealant component, preferably a base component (B) and a hardener component (H), by rotating a mixing rotor that engages into the paste-like mass in the mixing chamber. The temperature of the paste-like mass is measured by a temperature sensor and the measured temperature values are transmitted to a control unit. The speed of rotation of the mixing rotor is controlled by the control unit as a function of the temperature measured by the temperature sensor.

### BACKGROUND OF THE INVENTION

1. Field of the Invention

The invention relates to a method and a device for applying a paste-like mass.

2. The Prior Art

Two-component adhesives or sealants are generally produced in a mixing chamber of an application head. The components are separately introduced into the mixing chamber and mixed with one another there, by means of a mixing rotor. The adhesive or sealant mixed together in this manner is applied to a work piece via an application nozzle. As soon as the two components have been mixed with one another, the adhesive or sealant begins to react or cure. Before the so-called pot life, at which the adhesive or sealant can no longer be processed, has been reached, the material situated in the mixing chamber must be removed. The pot life is dependent on the temperature in the mixing chamber. This temperature is influenced by mixing the two components, since heat is released as the result of the reaction of the two components and as the result of friction during mixing. Rapid mixing, brought about by a high speed of rotation of the mixing rotor, therefore brings about a higher temperature in the mixing chamber. It is true that the dependence of the temperature on the speed of rotation of the mixing rotor is known for most two-component adhesives or sealants, so that the pot life can be estimated on the basis of the speed of rotation that has been set. However, the dependence between temperature and speed of rotation and therefore also the pot life can vary significantly even if variations in material consistency are only slight.

### SUMMARY OF THE INVENTION

It is therefore an object of the invention to provide a method and/or a device for mixing a two-component sealant or adhesive where the pot life can be kept approximately constant.

This object is accomplished, according to the invention, by a method for applying a two component paste-like mass onto a work piece, which mass is formed in a mixing chamber of an application head, by mixing at least one first and one second adhesive or sealant component, preferably a base component (B) and a hardener component (H). A mixing rotor that engages into the paste-like mass in the mixing chamber is rotated and the temperature of the paste-like mass is measured by a temperature sensor. The measured temperature values are transmitted to a control unit, and the speed of rotation of the mixing rotor is controlled by the control unit as a function of the temperature measured by the temperature sensor.

The invention is based on the idea that the temperature essentially determined by the heat of reaction of the adhesive or sealant components can be controlled to a value that is at least approximately constant, by means of measuring the temperature of the paste-like mass and controlling the speed of rotation of the mixing rotor as a function of the temperature, so that a pot life that can be predicted in relatively precise manner is obtained. The temperature measurement can optionally take place with a temperature sensor that is in contact with the paste-like mass, a sensor in the application head, to which the heat of the paste-like mass is transmitted by way of heat conduction, or without contact, for example by a temperature sensor that detects the heat radiation from the paste-like mass that exits from the application head.

The speed of rotation of the mixing rotor is preferably reduced if the temperature measured by the temperature sensor is above a predetermined reference temperature, and the speed of rotation of the mixing rotor is increased if the temperature measured by the temperature sensor is below the reference temperature. An increase in the speed of rotation results in stronger mixing and more rapid release of the heat of reaction. This results in an increase in the temperature of the paste-like mass, while a reduction in the speed of rotation results in a decrease in the temperature. Preferably, the speed of rotation of the mixing rotor is regulated to be between a predetermined minimal speed of rotation and a predetermined maximal speed of rotation. The speed of rotation window established by these predetermined speeds of rotation decides the possible speeds of rotation of the mixing rotor. Setting of a minimal speed of rotation is advantageous because if the speed of rotation is too low, insufficient mixing of the two components occurs. Setting of a maximal speed of rotation is advantageous because overly great mechanical stress on the application head, primarily of the seals, occurs at an overly great speed of rotation.

According to a first embodiment, the speed of rotation of the mixing rotor is continuously controlled by measuring the temperature at predetermined time intervals. This allows a constant adaptation of the speed of rotation. Generally, however, the paste-like mass is applied in application cycles that each include an application process and a rest phase, during which no application takes place. The mixing rotor is generally rotated only during the application process. In this connection, there is the possibility that the temperature measured by the temperature sensor during an application cycle, during the application process, is used to control the speed of rotation of the mixing rotor during a subsequent application cycle. While this type of control does not have the accuracy of continuous control, it requires less effort.

It is practical if the increase or reduction in the speed of rotation takes place proportional to the difference between the temperature measured by the temperature sensor and the reference temperature. For this purpose, the control unit has a proportional controller. A calibration curve that characterizes the dependence of the temperature of the paste-like mass on the speed of rotation can be determined before application of the paste-like mass, and stored in the memory of the control unit.

The temperature in the mixing chamber is preferably measured at an exit opening for the paste-like mass. There, the two components have been mixed together well and have reacted with one another to a great extent, so that the heat of reaction has already been released. At this location, the temperature measurement is therefore particularly informative.

### BRIEF DESCRIPTION OF THE DRAWINGS

Other objects and features of the present invention will become apparent from the following detailed description considered in connection with the accompanying drawings. It is to be understood, however, that the drawings are designed as an illustration only and not as a definition of the limits of the invention.

In the drawings, wherein similar reference characters denote similar elements throughout the several views:

FIG. 1 shows a schematic representation of an application device for a paste-like mass according to one embodiment of the invention; and

FIG. 2 shows a control curve for controlling the speed of rotation as a function of the measured temperature.

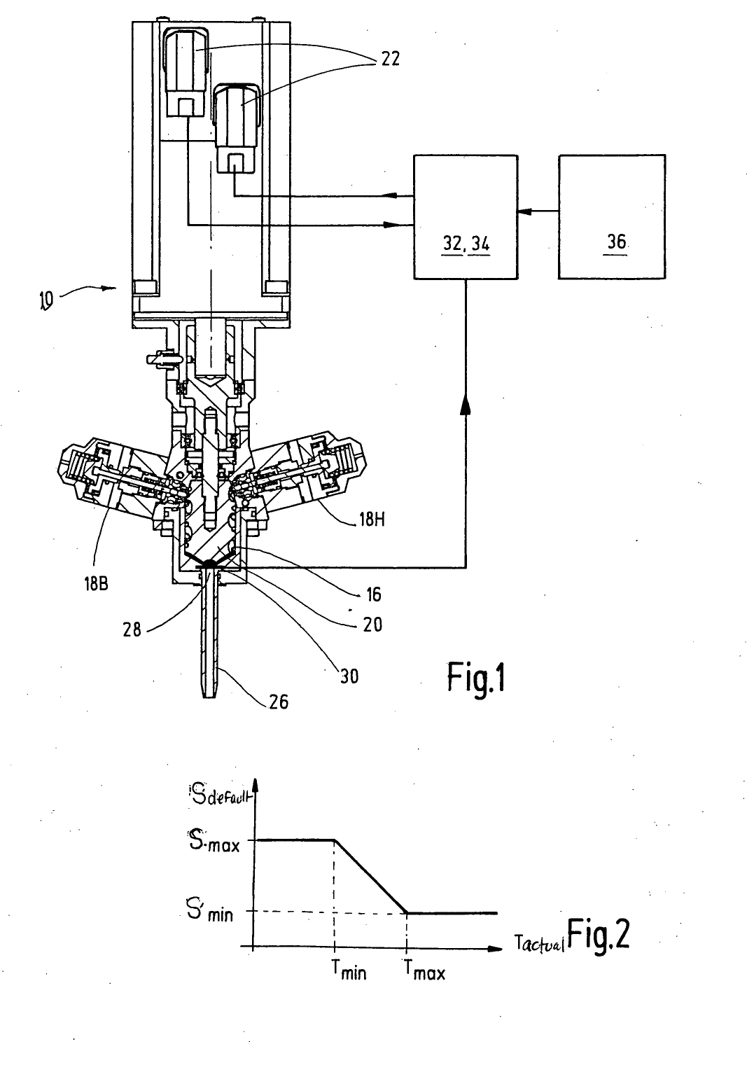

### DETAILED DESCRIPTION OF THE PREFERRED EMBODIMENT

A device for applying a two-component adhesive consisting of a base component B and a hardener component H has an application head 10 in which components B and H are brought together and mixed in a mixing chamber 16. Application head 10 has two metering valves 18B, 18H, by way of which components B, H are supplied to mixing chamber 16, under pressure. A mixing rotor 20 projects into mixing chamber 16; it is rotated to mix components B, H by means of a motor 22. The adhesive formed from components B, H is applied to a work piece by way of an application nozzle 26, with metering valves 18B, 18H being open, by means of applying pressure to the material that continues to flow.

At an exit opening 28 for the adhesive, which leads to application nozzle 26, a temperature sensor 30 is positioned in the application head 10, which sensor is connected with a control unit 32. The temperature in the mixed adhesive in mixing chamber 16 is measured by temperature sensor 30, which stands in contact with the adhesive, and the measured temperature value (actual value) is passed to control unit 32. Control unit 32 is connected with motor 22 and determines its speed of rotation, at which mixing rotor 20 is supposed to be rotated. Control unit 32 receives data concerning the current speed of rotation from the motor 22. If the measured temperature is above a predetermined reference value, the speed of rotation of the motor is reduced by control unit 32. Analogously, the speed of rotation of the motor is increased by controlling the motor by control unit 32 if the measured temperature is below the predetermined reference value. A higher speed of rotation of motor 22 and therefore of mixing rotor 20 results in better mixing of components B, H, so that the heat of reaction that occurs as they react is released more rapidly. As a result, the temperature in mixing chamber 16 is increased. Analogously, the temperature in mixing chamber 16 drops if the speed of rotation of mixing rotor 20 is reduced.

Control unit 32 has a proportional controller 34. The speed of rotation of mixing rotor 20 is increased or reduced proportional to the difference between the temperature measured by the temperature sensor and the predetermined reference temperature, by means of proportional controller 34. For this purpose, several parameters are put into the control unit before the adhesive application begins, by way of an input unit 36. These are the benchmark values Sₘᵢₙ, Sₘₐₓ, Tₘᵢₙ, and Tₘₐₓ, as well as the linear rise of the control curve, according to FIG. 2, between these benchmark values. Furthermore, a reference temperature T_{ref} is predetermined, which represents the reference value of the temperature of the paste-like mass. Reference temperature T_{ref} is between temperatures Tₘᵢₙ and Tₘₐₓ. The reference speed of rotation S_{ref} is assigned to reference temperature T_{ref}; mixing rotor 20 is rotated at this speed of rotation, at first. Then, the actual temperature value T_{actual} of the adhesive is measured at constant time intervals, and passed to control unit 32. The control unit sets the following speed of rotation S_{default} for the motor 22, from the predetermined and measured values:
S_{default}=S_{ref}+(T_{ref}−T_{actual})*(Sₘₐₓ−Sₘᵢₙ)/(Tₘₐₓ−Tₘᵢₙ)*K

In FIG. 2, the predetermined speed of rotation is plotted above the measured temperature, knowing that the speed of rotation can only vary in a speed of rotation window between a minimal speed of rotation Sₘᵢₙ and a maximal speed of rotation Sₘₐₓ. K is a correction value, which can be entered into the input unit 36 manually, and with which non-linearities in a calibration curve determined before application of the paste-like mass, for example, which curve characterizes the dependence of the temperature on the speed of rotation, can be taken into consideration. As a standard, K=1.

In summary, the following should be stated:

The invention relates to a method for applying a paste-like mass, having an adhesive or sealant that can cure and consists of at least two components, onto a work piece, which mass is formed in a mixing chamber 16 of an application head 10, by mixing at least one first and one second adhesive or sealant component, preferably a base component B and a hardener component H. A mixing rotor 20 that engages into the paste-like mass in mixing chamber 16 is rotated. According to the invention, the temperature of the paste-like mass is measured by means of a temperature sensor 30, and the measured temperature values are transmitted to a control unit 32. The speed of rotation of the mixing rotor 20 is controlled by the control unit 32 as a function of the temperature measured by temperature sensor 30.

Accordingly, while only a few embodiments of the present invention have been shown and described, it is obvious that many changes and modifications may be made thereunto without departing from the spirit and scope of the invention.

What is claimed is:

1. Method for applying a paste-like mass having an adhesive or sealing that can harden or cure and which consists of at least two components, onto a work piece, comprising the following steps:
forming the paste-like mass by mixing at least one first component and at least one second component in a mixing chamber of an application head by rotating a mixing rotor that engages into the paste-like mass in the mixing chamber;
measuring a temperature of the paste-like mass with a temperature sensor;
transmitting measured temperature values to a control unit; and
controlling a speed of rotation of the mixing rotor by the control unit as a function of the temperature measured by the temperature sensor.

2. A method according to claim 1, wherein the speed of rotation of the mixing rotor is reduced if the temperature measured by the temperature sensor is above a predetermined reference temperature, and the speed of rotation of the mixing rotor is increased if the temperature measured by the temperature sensor is below the reference temperature.

3. A method according to claim 1, wherein a speed of rotation of the mixing rotor is controlled to be between a predetermined minimal speed of rotation and a predetermined maximal speed of rotation.

4. A method according to claim 1, wherein a speed of rotation of the mixing rotor is continuously controlled by measuring the temperature at predetermined time intervals.

5. A method according to claim 1, wherein the paste-like mass is applied in application cycles and the temperature measured by the temperature sensor during an application cycle is used to control the speed of rotation of the mixing rotor during a subsequent application cycle.

6. A method according to claim 2, wherein an increase or reduction in a speed of rotation takes place proportional to a difference between the temperature measured by the temperature sensor and the reference temperature.

7. A method according to claim 1, further comprising the step of determining a calibration curve that characterizes a dependence of the temperature of the paste-like mass on the speed of rotation, before application of the paste-like mass, said calibration curve being stored in a memory of the regulation unit.

8. A method according to claim 1, wherein the temperature is measured by a temperature sensor that is in contact with the paste-like mass.

9. A method according to claim 1, wherein the temperature sensor is disposed outside of the mixing chamber in the application head and measures the temperature indirectly.

10. A method according to claim 8, wherein the temperature is measured at an exit opening for the paste-like mass.

11. A method according to claim 1, wherein the temperature is measured by detecting heat radiation from the paste-like mass that exits from the application head.

12. A device for applying a paste-like mass having an adhesive or sealant that can cure and which consists of at least two components, onto a work piece, comprising:
an application head having a mixing chamber for forming the paste-like mass by mixing the at least two components;
a mixing rotor disposed in the application head, said mixing rotor projecting into the mixing chamber and being rotated by a drive motor;
a temperature sensor for measuring the temperature of the paste-like mass; and
a control unit for controlling a speed of rotation of the mixing rotor as a function of the temperature measured by the temperature sensor.

13. A device according to claim 12, wherein the temperature sensor is disposed in the mixing chamber and is in contact with the paste-like mass.

14. A device according to claim 12, wherein the temperature sensor is disposed outside of the mixing chamber in the application head.

15. A device according to claim 14, wherein the temperature sensor is disposed at an exit opening for the paste-like mass, in the application head.

16. A device according to claim 12, wherein the temperature sensor is a radiation sensor for detecting heat radiation of the paste-like mass that exits from the application head.

17. A device according to claim 12, wherein the control unit has a proportional controller.
